(19) United States
(12) Patent Application Publication
(10) Pub. No.: US 2008/0302416 A1
(43) Pub. Date: Dec. 11, 2008

(54) Durable silver based transparent conductive coatings for solar cells

(75) Inventors: Jesse Dennis Wolfe, Bullhead City, AZ (US); Robert Cart, Berkeley, CA (US)

Correspondence Address: VAN PELT, YI & JAMES LLP, 10050 N. FOOTHILL BLVD #200, CUPERTINO, CA, 95014, US

(73) Assignee: GREEN VOLTS, INC.

(21) Appl. No.: 12/157,194

(22) Filed: Jun. 5, 2008

Related U.S. Application Data
(60) Provisional application No. 60/933,368, filed on Jun. 5, 2007.

(51) Int. Cl. H01L 31/00

(52) U.S. Cl. 136/256

(57) ABSTRACT

A method of creating a solar cell package is disclosed. A solar cell is obtained having an active surface. A coating is applied to the active surface of the solar cell, wherein the coating comprises a four-layer structure. A first Nickel Chromium Nitride layer is applied with a thickness between 5-15 Angstroms inclusive. A Silver layer is applied to the first Nickel Chromium Nitride layer, wherein the Silver layer comprises at least 99.999% Silver with a thickness between 40-100 Angstroms inclusive. A second Nickel Chromium Nitride layer is applied to the Silver layer, wherein the second Nickel Chromium Nitride layer comprises a thickness between 5-15 Angstroms inclusive. A Silicon Nitride layer is applied to the second Nickel Chromium Nitride layer.

### CROSS REFERENCE TO OTHER APPLICATIONS

This application claims priority to U.S. Provisional Patent Application No. 60/933,368 (Attorney Docket No. GREEP006+) entitled COATING FOR SOLAR CELLS AND VISIBLE DISPLAYS filed Jun. 5, 2007 which is incorporated herein by reference for all purposes.

### BACKGROUND OF THE INVENTION

Solar cells, including photovoltaic cells, when used in space or on earth, alone or in combination with solar concentrators will heat up during exposure. This is detrimental to their efficiency; as temperature of a cell is increased beyond a threshold, its efficiency is lowered. Solar cells require a conductor to transport electrical current from the P-N junction along the active surface of the solar cell. An efficient, environmentally durable coating for solar cells would be desirable.

### BRIEF DESCRIPTION OF THE DRAWINGS

Various embodiments of the invention are disclosed in the following detailed description and the accompanying drawings.

FIG. 1A is a diagram illustrating a cross-sectional view of an embodiment of a solar cell without a transparent conductive coating.

FIG. 1B is a diagram illustrating a plan view of an embodiment of a solar cell without a transparent conductive coating.

FIG. 2A is a diagram illustrating a cross-sectional view of an embodiment of a solar cell with a transparent conductive coating.

FIG. 2B is a diagram illustrating a plan view of an embodiment of a solar cell with a transparent conductive coating.

FIG. 3A is a graph illustrating an optimal efficiency curve of a solar cell.

FIG. 3B is a plot of the three efficiency curves of an example triple-junction cell.

FIG. 4 is a diagram illustrating a cross-sectional view of an embodiment of a durable silver based transparent conductive Blue/Red reflector coating for a solar cell.

FIG. 5 is a diagram illustrating a cross-sectional view of an embodiment of a durable silver based transparent conductive Blue/Red reflector coating for a solar cell with more than one four-layer structure.

FIG. 6 is a flowchart illustrating a method to create a durable silver based transparent conductive Blue/Red reflector coating for a solar cell.

FIG. 7 is a flowchart illustrating a method to apply a durable silver based transparent conductive Blue/Red reflector coating to the active surface of a solar cell.

FIG. 8 is a graph of a 72 layer silver based Blue/Red reflector on AIInP solar cells.

FIG. 9 is a graph of the index of refraction of two silver metal films 45 and 60 Angstroms in thickness.

FIG. 10 is a graph of the extinction coefficient (k) of two silver films.

FIG. 11 is a chart of (k/n) for each of the two silver films 45 & 60 Angstroms thick vs. wavelength in nm.

FIG. 12 is a graph of (k/n) for each of the two silver films 45 & 60 Angstroms thick vs. wavelength in nm.

FIG. 13 is a graph of the optical and electrical performance of a 9-layer coating on an InGaP solar cell.

FIG. 14 is a graph of the reflection and transmission of a 20-layer coating on an InGaP solar cell.

FIG. 15 is a graph of a 10-layer design with an 85 Angstrom thick layer of poly-silicon.

FIG. 16 is a graph of a 9-layer design with an 85 Angstrom thick layer of poly-silicon and 70 Angstroms thick layer of silver.

FIG. 17 is a graph of the reflection and transmission of a 23-layer dual silver design.

FIG. 18 is a graph of the reflection and transmission of a 19-layer dual silver design for a silicon solar cell.

FIG. 19 is a graph of the reflection, transmission, and absorption of 50 Angstroms of pure silver on a 2 mm fused silica substrate.

FIG. 20 is a graph of 50 Angstroms of a tri-layer on 2 mm fused substrate.

FIG. 21 is a graph of the k/n for gold and silver, both 60 Angstroms thick.

FIG. 22 is a graph of the transmission for a 28-layer ITO/Ag/ITO design in comparison to a 43-layer AgAR design.

FIG. 23 is a graph of the silver conductivity versus thickness in Angstroms.

### DETAILED DESCRIPTION

The invention can be implemented in numerous ways, including as a process, an apparatus, a system, or a composition of matter. In this specification, these implementations, or any other form that the invention may take, may be referred to as techniques. A component such as a solar cell described as being configured to perform a task includes both a general component that is temporarily configured to perform the task at a given time or a specific component that is manufactured to perform the task. In general, the order of the steps of disclosed processes may be altered within the scope of the invention. As used herein, the term ‘cell’ or ‘solar cell’ refers to one or more devices that converts sunlight to power, such as a photovoltaic cell.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Durable silver based thin film vacuum deposited coatings, which acts as an anti-reflection coating on various substrates, are electrically conductive, and provide high transmission across extremely wide-bandwidths. The coatings are environmentally durable and are more electrically conducting than other types of coatings used for this application. In this particular application we show how the films can be used on various solar cell substrates to replace the solid metal films now used to gather the current, and improve the efficiency of solar cells.

These films can be used on a range of solar cells as transparent, electrically conductive films. They allow elimination of some or all of the metal contacts on the cell face, anti-reflect the cell surface, improve transmission, and increase cell efficiency. The films also provide some EMI/RFI shielding, and are environmentally durable.

These thin film coatings are designed to replace the metal contacts on the face of solar cells, which are used to gather and conduct the electrical current from the cell junctions. In some embodiments, the coating is transparent, electrically conductive, and does not shadow the surface of the cell as the nominal used thick metal does. The coating also anti-reflects the surface of the cell. In some embodiments, the coating is based on durable silver, which does not degrade when used in harsh environments. The coating is 45× more conductive per thickness than indium tin oxide. It does not require heated substrate temperatures to apply, and is bendable when deposited on plastic substrates. Indium tin oxide coatings are brittle and have a problem with thickness vs. intrinsic stress. This described silver based design contains low intrinsic stress, and can be applied to various substrates, including, but not limited to silicon, gallium arsenide, cadmium sulfide, glass and plastics.

In some embodiments, a coating is applied to reflect the damaging ultraviolet (“UV”) and infrared (“IR”) wavelengths of light. These coatings are made up of all dielectric layers, and are known as “Blue/Red” reflectors. The coatings are designed to transmit the portion of the spectrum that the cell can use to function, and reflect the portions that are detrimental. The described silver based coating design can function as a Blue/Red reflector, and transparent conductive coating all-in-one coating.

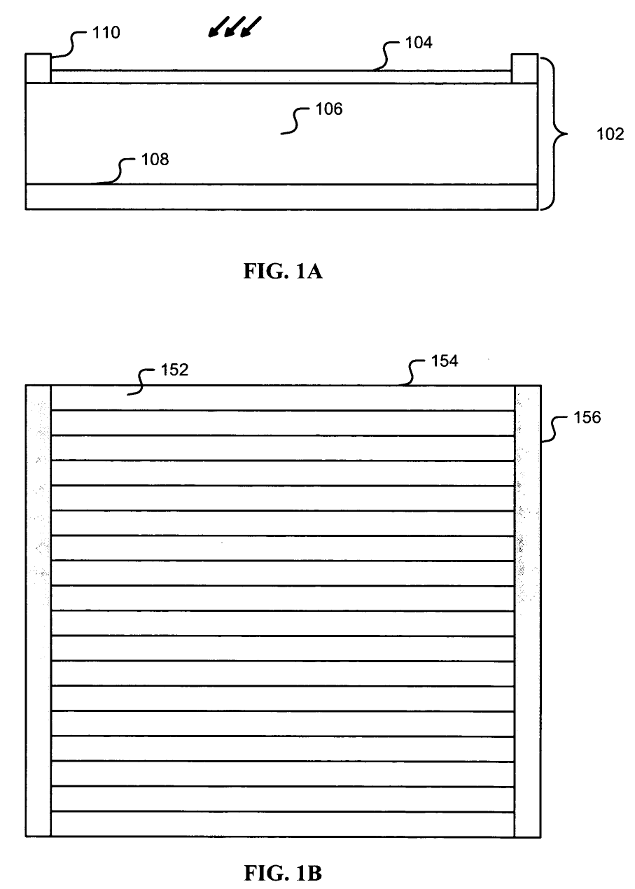

FIG. 1A is a diagram illustrating a cross-sectional view of an embodiment of a solar cell without a transparent conductive coating. Solar cell 102 includes silver contacts or “fingers” 104 drawn across the active surface of the cell to conduct electrical current from the cell P-N junctions 106, completing the circuit with bottom contact 108. The silver fingers 104 collect current for distribution to larger busbars 110. FIG. 1B is a diagram illustrating a plan view of an embodiment of a solar cell without a transparent conductive coating. A percentage of the cell junction 152 is exposed to solar radiation but obscured by the silver fingers 154 and busbars 156.

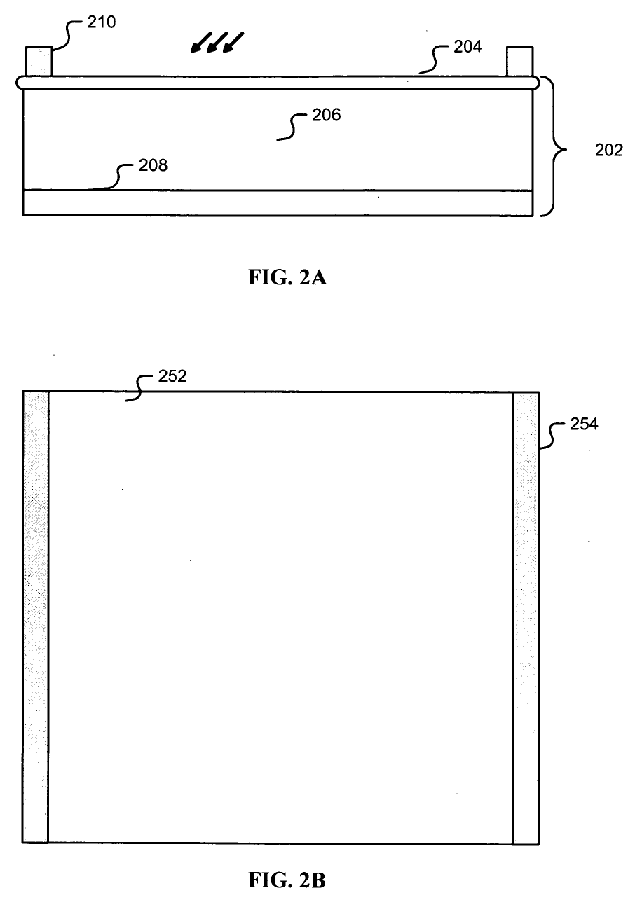

FIG. 2A is a diagram illustrating a cross-sectional view of an embodiment of a solar cell with a transparent conductive coating. Solar cell 202 includes a silver based coating 204 to conduct electrical current from the cell P-N junctions 206, completing the circuit with bottom contact 208. The silver coating 204 collects current for distribution to larger busbars 210. FIG. 2B is a diagram illustrating a plan view of an embodiment of a solar cell with a transparent conductive coating. The cell junction 252 is not obscured by silver fingers 154 but only the necessary busbars 254, decreasing the shading loss from the silver fingers 154 and increasing the efficiency of the solar cell.

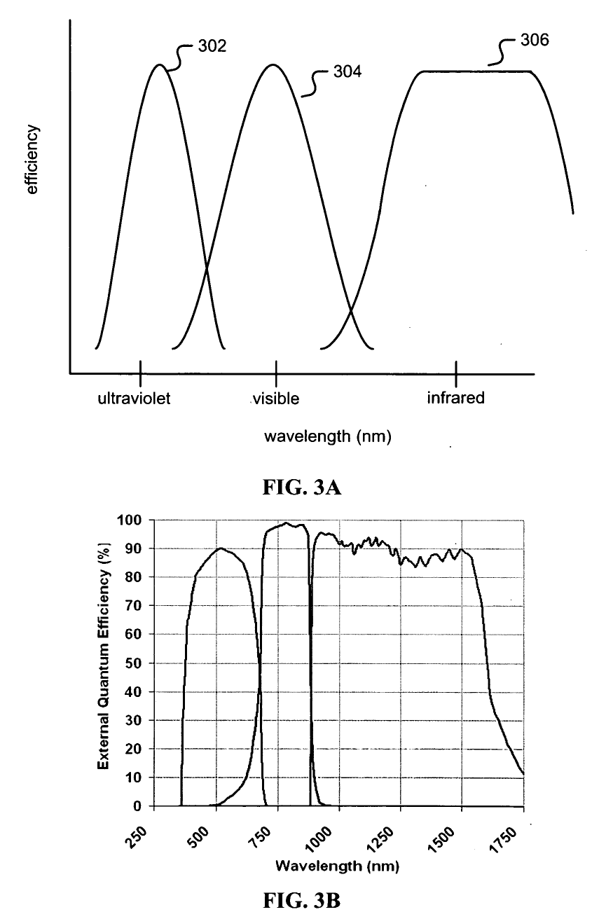

FIG. 3A is a graph illustrating an optimal efficiency curve of a solar cell. The graph x-axis represents wavelength and graph y-axis represents efficiency of the solar cell. In some embodiments the solar cell is a triple-junction cell with a top semiconductor efficiency curve 302, a middle semiconductor efficiency curve 304, and a bottom semiconductor efficiency curve 306. In some embodiments the solar cell is a silicon cell with a single efficiency curve 304. In some embodiments, the top semiconductor is an Indium Gallium Phosphide (“InGaP”) semiconductor with an optimal efficiency 302 in the ultraviolet spectrum. In some embodiments, the middle semiconductor is a Gallium Arsenide (“GaAs”) semiconductor with an optimal efficiency 304 in the visible spectrum. In some embodiments, the bottom semiconductor is a Germanium (“Ge”) semiconductor with an optimal efficiency 306 in the infrared spectrum.

A Blue/Red reflector coating, by rejecting wavelengths smaller than the curve 302 and rejecting wavelengths larger than the curve 306, can increase the efficiency of the solar cell. Similarly, a transmissive coating that reduces refractive losses for wavelengths included within curves 302, 304 and 306, will also increase the efficiency of the solar cell. FIG. 3B is a plot of the three efficiency curves of an example triple-junction cell. For example, a Blue/Red reflector coating can reject wavelengths smaller than ˜350 nm and higher than ˜1550 nm. By allowing light to pass with minimal adsorption in the wavelength range of about 350 nm to 1550 nm, the solar cell can provide is highest possible output.

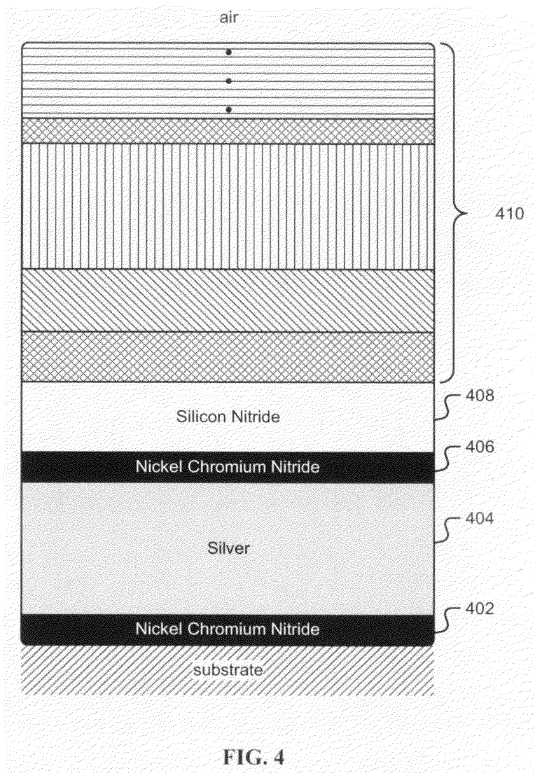

FIG. 4 is a diagram illustrating a cross-sectional view of an embodiment of a durable silver based transparent conductive Blue/Red reflector coating for a solar cell. In some embodiments, the coating of FIG. 4 is the coating 204 of FIG. 2A. On the active surface substrate of the solar cell a coating is applied that includes a “four-layer structure”, wherein the four-layer structure includes:
1. A first Nickel Chromium Nitride layer 402 with a thickness between 5-15 Angstroms inclusive;
2. a Silver layer 404, includes at least 99.999% Silver with a thickness between 40-100 Angstroms inclusive, is applied to the first Nickel Chromium Nitride layer;
3. a second Nickel Chromium Nitride layer 406 with a thickness between 5-15 Angstroms inclusive is applied to the Silver layer; and
4. a Silicon Nitride layer 408 is applied to the second Nickel Chromium Nitride layer.

In some embodiments, additional dielectric layers 410 are applied. In some embodiments, the dielectric layers 410 adjust the rejection/reflective characteristics and refractive/antireflective characteristics of the coating to match curves 302, 304, and 306. In some embodiments, the individual composition and thickness of dielectric layers 410 is used to adjust the reflective and antireflective characteristics of the coating.

In some embodiments, the four-layer structure is applied directly to the active surface. In some embodiments, the Nickel Chromium Nitride layers 402 and 406 include NiCrNₓ. In some embodiments, the Nickel Chromium Nitride layers 402 and 406 include Nichrome sputtered in Nitrogen gas, for example an atomic mixture of 80% Nickel 20% Chrome sputtered in 100% Nitrogen gas. In some embodiments, the Silicon Nitride layer includes SiₓN_{y}, or Si₃N₄.

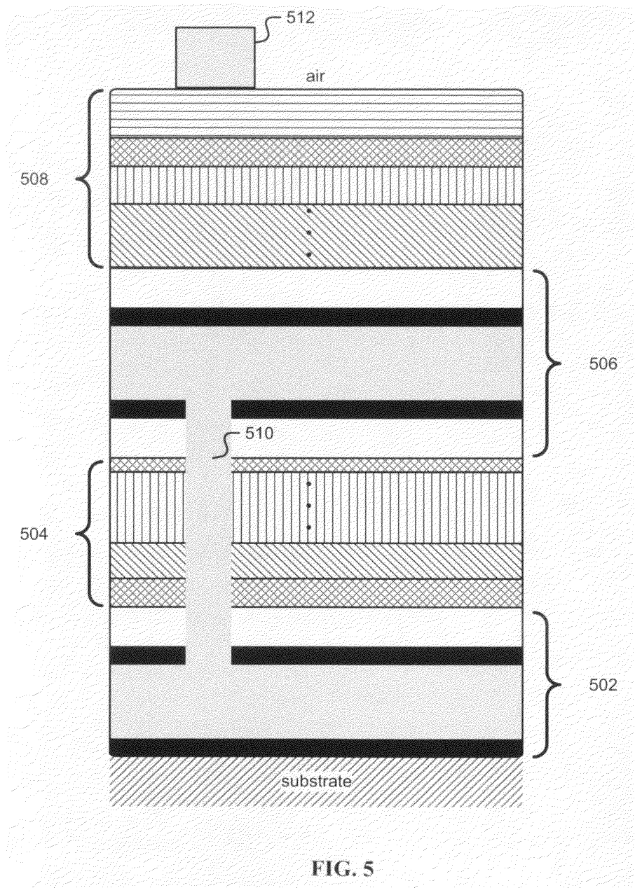

FIG. 5 is a diagram illustrating a cross-sectional view of an embodiment of a durable silver based transparent conductive Blue/Red reflector coating for a solar cell with more than one four-layer structure. In some embodiments, the coating of FIG. 5 is the coating 204 of FIG. 2A. In the example shown, a first four-layer structure 502 is applied to the active surface substrate. A first set of dielectric layers 504 are applied to the top of the first four-layer structure 502. An additional four-layer structure 506 is applied to the top of the first set of dielectric layers 504.

An additional set of dielectric layers 508 is applied to the top of the additional four-layer structure 506. A via 510 connects the first four-layer structure 502 to the additional four-layer structure 506. By adding and connecting the first four-layer structure 502 and additional four-layer structure 506 within the coating, the overall resistivity of the coating is decreased. In some embodiments, the shading effect of via 510 is reduced by placing it under busbar 512, taking into effects refraction, as the busbar is already shading the solar cell.

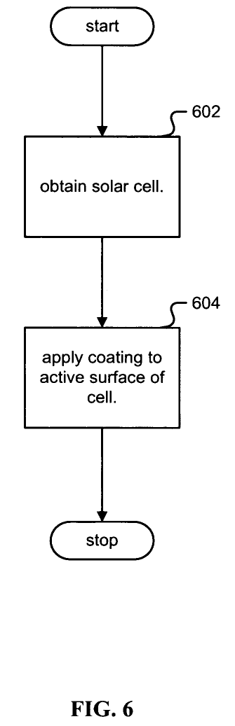

FIG. 6 is a flowchart illustrating a method to create a durable silver based transparent conductive Blue/Red reflector coating for a solar cell. In step 602 a solar cell is obtained and prepared for the application of a coating. In step 604 a durable silver based transparent conductive Blue/Red reflector coating is applied to the active surface of the solar cell.

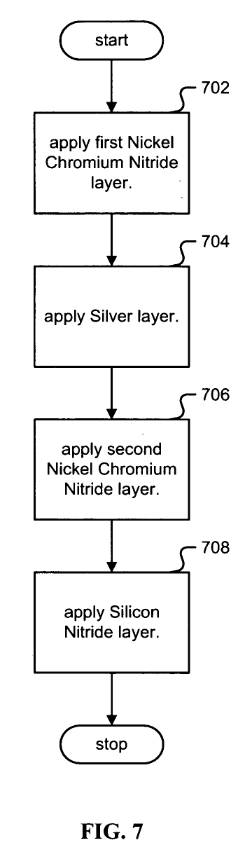

FIG. 7 is a flowchart illustrating a method to apply a durable silver based transparent conductive Blue/Red reflector coating to the active surface of a solar cell. In some embodiments the method of FIG. 7 is included in step 604 of FIG. 6. In step 702, a first Nickel Chromium Nitride layer with a thickness between 5-15 Angstroms inclusive is applied. In step 704, a Silver layer, includes at least 99.999% Silver with a thickness between 40-100 Angstroms inclusive, is applied to the first Nickel Chromium Nitride layer. In step 706, a second Nickel Chromium Nitride layer with a thickness between 5-15 Angstroms inclusive, is applied to the Silver layer. In step 708, a Silicon Nitride layer is applied to the second Nickel Chromium Nitride layer.

Features of coating. In some embodiments, there are three features of the durable silver based transparent conductive Blue/Red reflector coating described above:
1. The coating has very broadband, from at least 350 nm to 1500 nm, antireflective properties, especially in the UV and visible wavelengths, and is electrically conductive;
2. the coating performs optically better than any other conductive transparent coating, especially in UV wavelengths;
3. the coating is environmentally durable, and will pass humidity tests, acid baths and Sulfur Dioxide exposure.

The UV and visible portions of the solar spectrum are especially important to concentrator PV technology and space applications where III-V materials are most commonly used, particularly the use of triple junction solar cells where in some embodiments the top GaInP cell can have a bandgap between 1.70-1.9 eV. New solar cell materials may have higher bandgap, and so a shorter wavelength, for the top cell and the window layers for the top cell. In some embodiments AlInP has a higher band gap, about 2.5 eV. In some embodiments, the middle and bottom cells are GaAs and InGaP with bandgaps of 1.4 eV and 1.0 eV respectively.

Collecting as much light energy as possible in the 1.65 eV to 3.6 eV, or 350-750 nm wavelength increases performance since the current is generated at higher voltages and therefore higher power than at longer wavelengths. Therefore an advantage of a durable silver based transparent conductive Blue/Red reflector coating is that it transmits a high proportion of the solar spectrum in the UV and visible wavelengths.

Because of its high index of refraction, the solar cell needs an antireflective (“AR”) coating to couple light into the solar cell. As an example, for the cell in FIG. 3B to be effective it needs an AR coating that transmits the light from about 350 nm to about 1550 nm. The durable silver based transparent conductive Blue/Red reflector coating is unique in that it transmitting much energy in UV and visible wavelengths, which is critical to the performance of the cell since most of the cell power is generated in the top InGaP layer and the middle GaAs layer. Low transmission of light means low power efficiency.

Although it is thin, the sheet resistance of the durable silver based transparent conductive Blue/Red reflector coating is low, in some embodiments between 5-30 ohm/square depending on thickness and number of silver layers. By comparison the resistance of the semiconductor window and contact layers is about 250-300 ohms/square, or higher.

One way of telling the optical transparency of a thin metal film is the ratio of its extinction coefficient to the refractive index (k/n). The higher the k/n value the better the transmission. Silver has the largest k/n ratio of any transparent metal in the near UV and visible portion of the spectrum, which makes it particularly valuable for III-V solar cells and some thin film solar cells.

The Silver layer 404 includes a purer silver, as alloying the silver with any material increases the adsorption in the UV, where it is most critical. In some embodiments, ITO (indium tin oxide) is used as a dielectric or UV resins. ITO and resins are not used for wide band gap (e.g. III-V based cells) solar cells such as are commonly used in concentrating photovoltaics and extra-terrestrial applications. They work for lower band gap materials like Silicon or Cadmium Sulfide but not with the wider gap cells because the ITO and resins are absorbing in the UV.

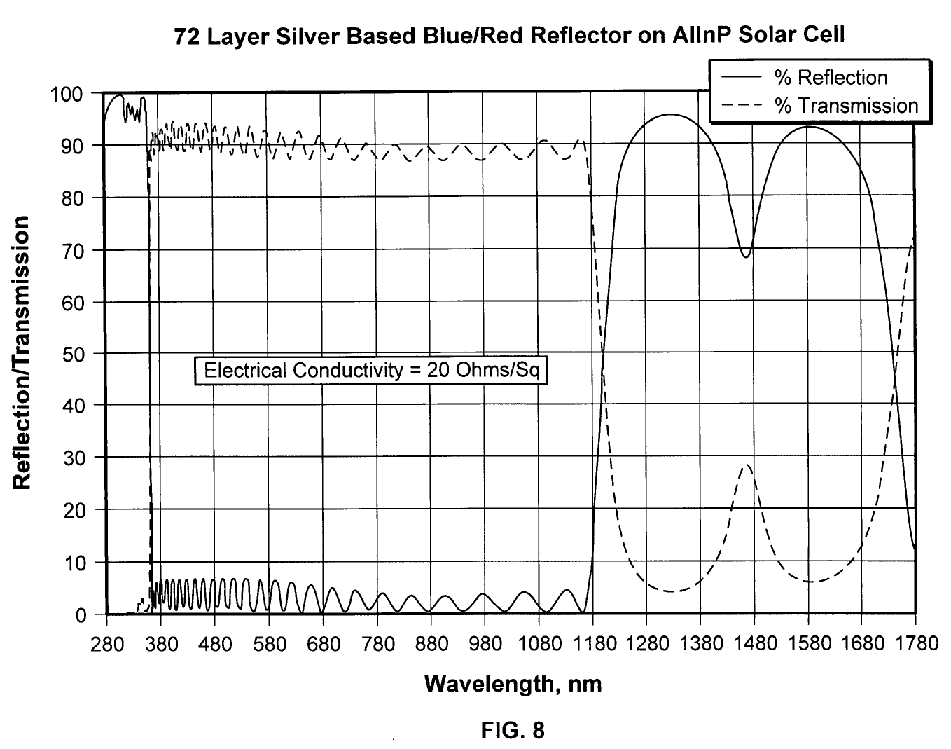

FIG. 8 is a graph of a 72 layer silver based Blue/Red reflector on AlInP solar cells. As shown in this example, the single coating rejects Blue/red wavelengths and enhances transmission of the UV, visible and infrared spectrum.

Notes on thin film silver metal layers. When a thin film of silver is deposited on a substrate such as Fused Silica (Glass), at room temperature, the film first forms small conglomerates or islands at about 5-10 Angstroms thickness. As growth continues these island conglomerate or grow together to form a continuous film at a thickness of about 40-50 Angstroms. The film is not electrically conductive until this solid film is formed.

During the last 10-20 Angstroms prior to the islands forming a continuous film, the optical properties change drastically. Just prior to the film being continuous, the voids between islands cause a drastic increase in optical absorption. When the islands form a continuous film there is a drastic decrease in absorption and the film becomes much more transparent. This is very noticeable when using an optical monitor, and looking at transmission. The transmission will decrease from about 100% to 10%, and then increase back to 95% or so.

The result of dividing the extinction coefficient (k), by the index of refraction (n), increases as the film becomes more continuous and electrically conductive, and also may have higher transmission at that wavelength. Higher k/n numbers indicate a better coating. An example comparison is made between Silver and Aluminum, which shows Silver is a superior component, as Bulk Silver @ 550 nm=3.545÷0.03=118.00; and Bulk Aluminum @ 550 nm=5.99÷0.82=7.30.

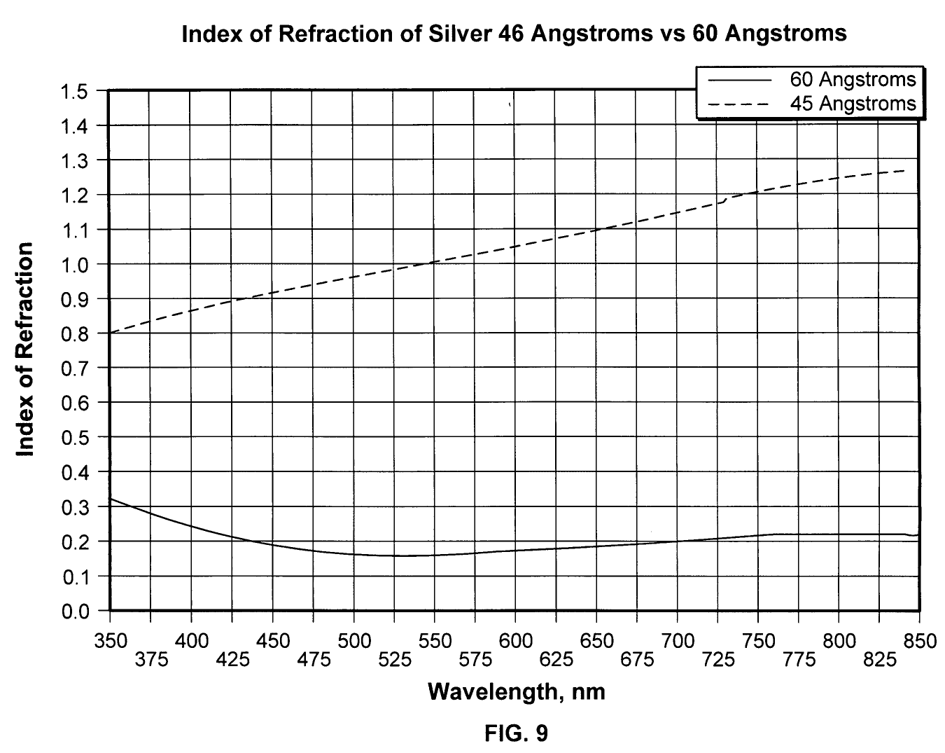

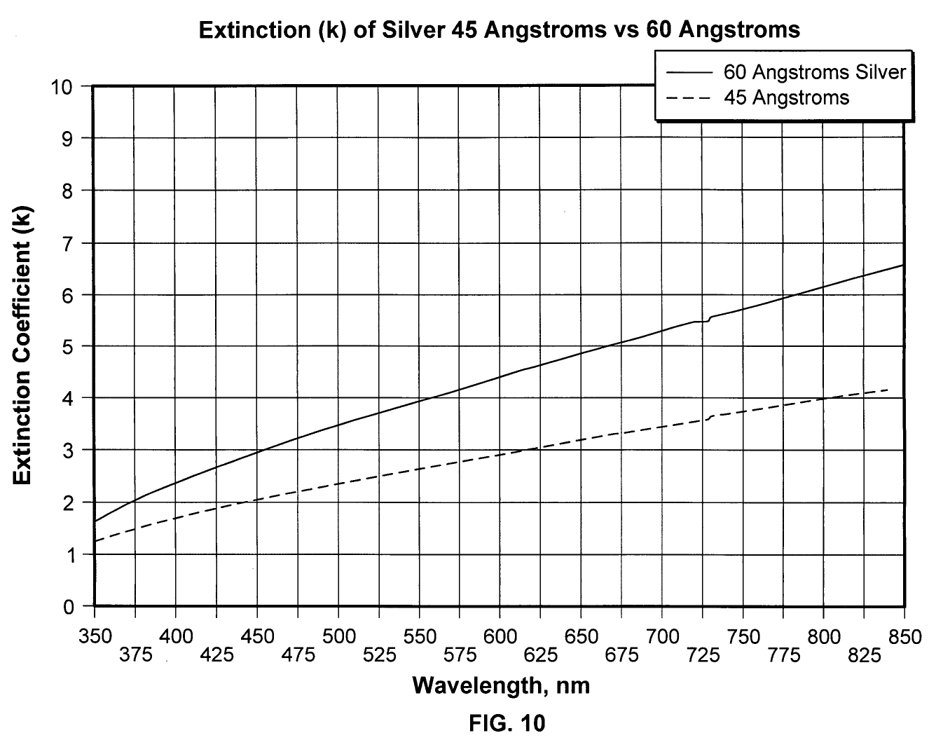

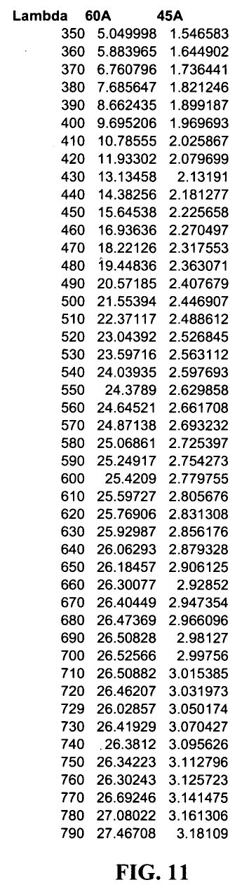

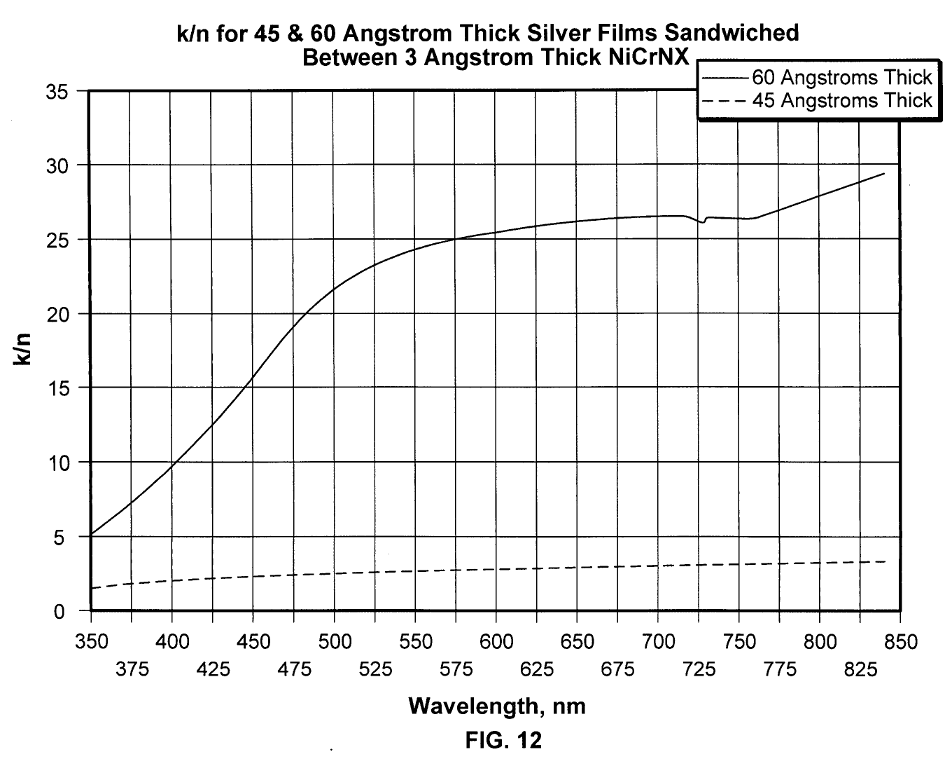

FIG. 9 is a graph of the index of refraction of two silver metal films 45 and 60 Angstroms in thickness. As shown in FIG. 9, the index is higher for the thinner film. For metals, the optical constants are a complicated number; A lower value for n, and a high value for k is superior. For example, a 99.999% pure film of silver 500 nm thick has an index of 0.030 and a extinction coefficient of 3.545 at 550 nm wavelength, so k/n=3.545÷0.03=118.00. FIG. 10 is a graph of the extinction coefficient (k) of two silver films. As shown in FIG. 10, the extinction value is lower for the thinner film. FIG. 11 is a chart of (k/n) for each of the two silver films 45 & 60 Angstroms thick vs. wavelength in nm. FIG. 12 is a graph of (k/n) for each of the two silver films 45 & 60 Angstroms thick vs. wavelength in nm.

A transparent durable silver coating for use on solar cells to replace the solid metal collection grid on the solar cell is disclosed.

In some embodiments, when depositing conductive materials on a solar cell, and using the material to transport the electrical current from the P-N junction, the conductive layer must be in contact with the active surface of the solar cell. This limits the use of most transparent materials except for ITO, SnO₂, AlZnO, and nano tube technology, which are electrically conductive. Furthermore, all of the materials mentioned have a high index of refraction and possess high intrinsic stress which make the films brittle. Most thin film vacuum deposited coating designs require a low index material in conjunction with a high index material.

In some embodiments, this coating consists of a layer of silver metal, which can vary in thickness from 40 to 100 Angstroms thick. The silver is sandwiched between two layers of NiCrNₓ approximately 5-15 Angstroms thick, and a layer of Si₃N₄ is deposited on top. The NiCrNₓ admixes with the silver film and ties up the electrons in the silver matrix, which impedes further degradation of the silver. The Si₃N₄ on top of the tri-layer of NiCrNₓ/Ag/NiCrNₓ is to stop any attack from atomic oxygen when sputter depositing further dielectric layers in the process that contain any oxygen, when depositing this design on solar cell materials, because of the high index of the solar material, 3.5-5.0, the substrate acts as an anti-reflecting film on the substrate side. This allows the Tri-layer of NiCrNₓ/Ag/NiCrNₓ to be deposited directly on the solar cell surface.

In some embodiments, dielectric layers of various materials and indices are deposited on the tri-layer and improve the optical transmission of the coating design. This is known as “induced transmission”, which may be used as a low emissivity coating design. When coatings are used for solar control on glass, the silver layer does not need to be next to the substrate, and can be embedded between layers in the coating stack. In some embodiments, two or more silver layers are separated by many dielectric layers.

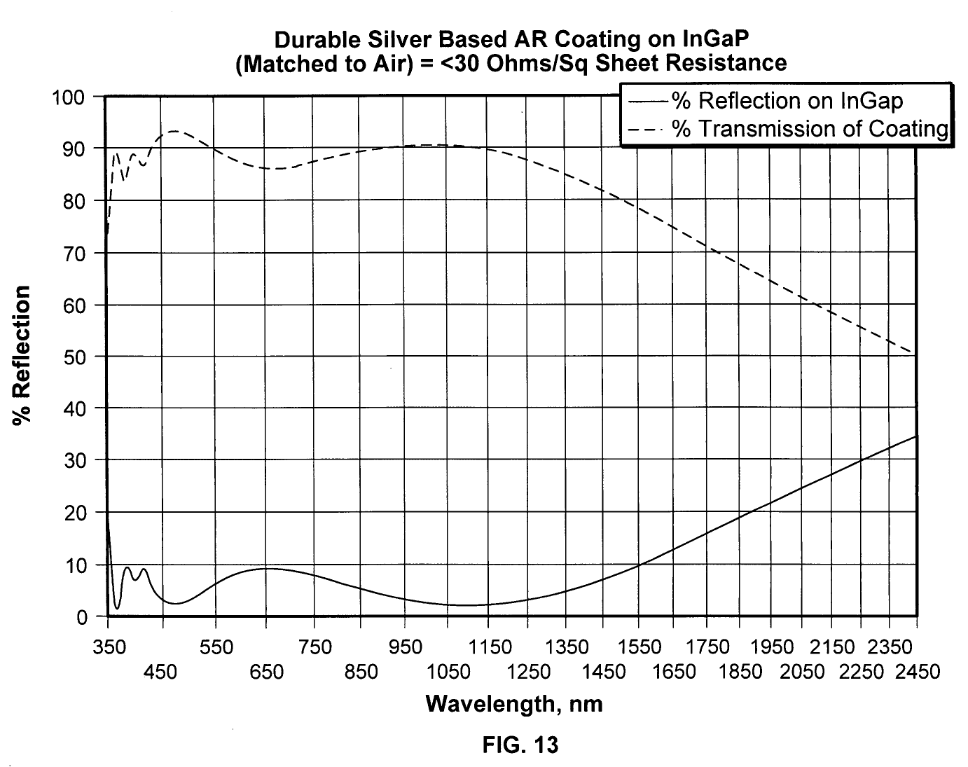

FIG. 13 is a graph of the optical and electrical performance of a 9-layer coating on an InGaP solar cell. The 9-layer coating includes the following layers:

| Layer: | | | | | | | | | |
|---|---|---|---|---|---|---|---|---|---|
| 1 | 2 | 3 | 4 | 5 | 6 | 7 | 8 | 9 | |
| Substrate | | | | | | | | | |
| NiCrNₓ | Silver | NiCrNₓ | SiₓN_{y} | TiO₂ | TaOₓ | SiO₂ | TiO₂ | MgF₂ | Air |
| 5A | 70A | 5A | 30A | 350A | 90A | 320A | 152A | 1016A | |

This is a coating design that uses materials that may be used by the coating industry. This design uses silver at a thickness of 60-80 Angstroms.

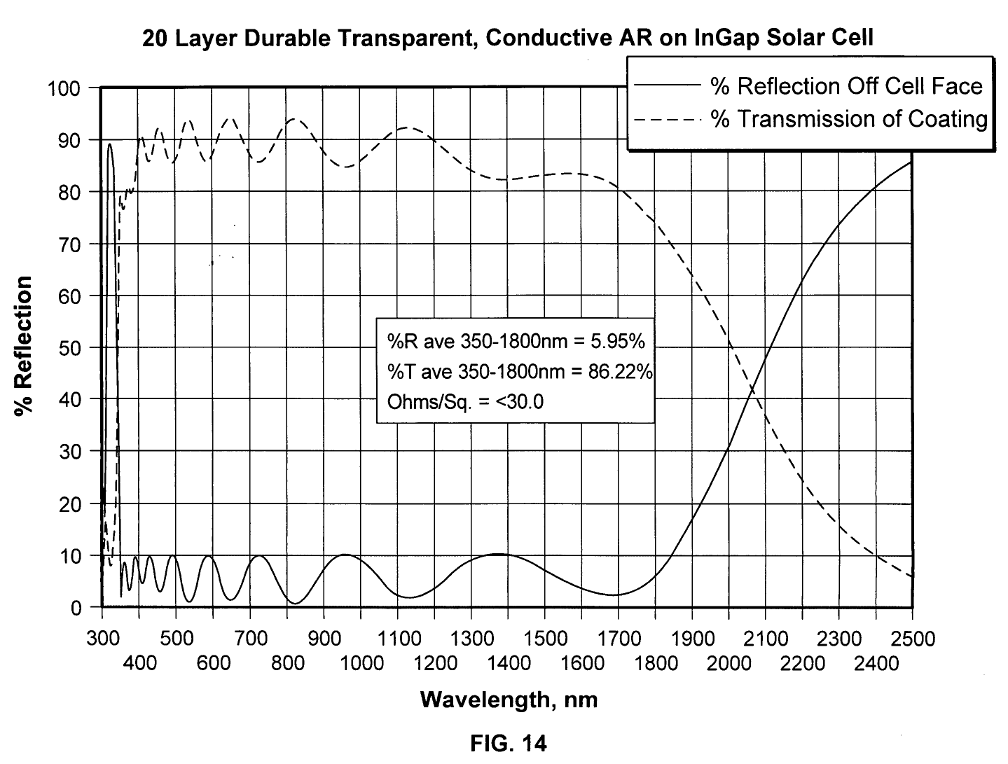

FIG. 14 is a graph of the reflection and transmission of a 20-layer coating on an InGaP solar cell. The 20-layer coating includes the following layers:

Layer:

| | | | | | | | | | | | |
|---|---|---|---|---|---|---|---|---|---|---|---|
| 1 | 2 | 3 | 4 | 5 | 6 | 7 | 8 | 9 | 10 | 11 | 12 |

Substrate

| NiCrNₓ | Silver | NiCrNₓ | SiₓN_{y} | TiO₂ | MgF₂ | TiO₂ | SiO₂ | TaOₓ | SiO₂ | TaOₓ | SiO₂ |
|---|---|---|---|---|---|---|---|---|---|---|---|
| 5A | 70A | 5A | 30A | 455A | 270A | 174A | 560A | 60A | 1640A | 112A | 526A |

| Layer: | | | | | | | | |
|---|---|---|---|---|---|---|---|---|
| 13 | 14 | 15 | 16 | 17 | 18 | 19 | 20 | |
| Substrate | | | | | | | | |
| TaOₓ | SiO₂ | TaOₓ | SiO₂ | TiO₂ | SiO₂ | TaOₓ | MgF₂ | Air |
| 310A | 230A | 1510A | 205A | 490A | 490A | 170A | 1200A | |

This is a coating design that uses materials that may be used by the coating industry. This design uses silver at a thickness of 60-80 Angstroms.

The Use of Semi-Crystallized Silicon in Designs.

In some embodiments, multi-junction solar cells require a bandwidth of 350-1800 nm or about a width that is 4-5 times wider than normal AR coatings. They also should be designed for very high index substrates such as a 4.0 to 5.0 index of refraction, and for use at multiple angles of incidence.

In some embodiments, a minimum reflection value across the 350 nm to 1800 nm spectrum is limited to about 6-8% average when standard coating materials are used in this process, This is because a high index material with an index equal to, or higher than the index of the substrate is needed to lower this value. A material, which has the required optical constants (n, k), does not exist. However, if silicon is deposited in a vacuum and ion gun assist (“Ion Gun assist”) is added with a substrate temperature of >250 C, a poly-crystalline silicon can be deposited. This may give the correct optical constants required.

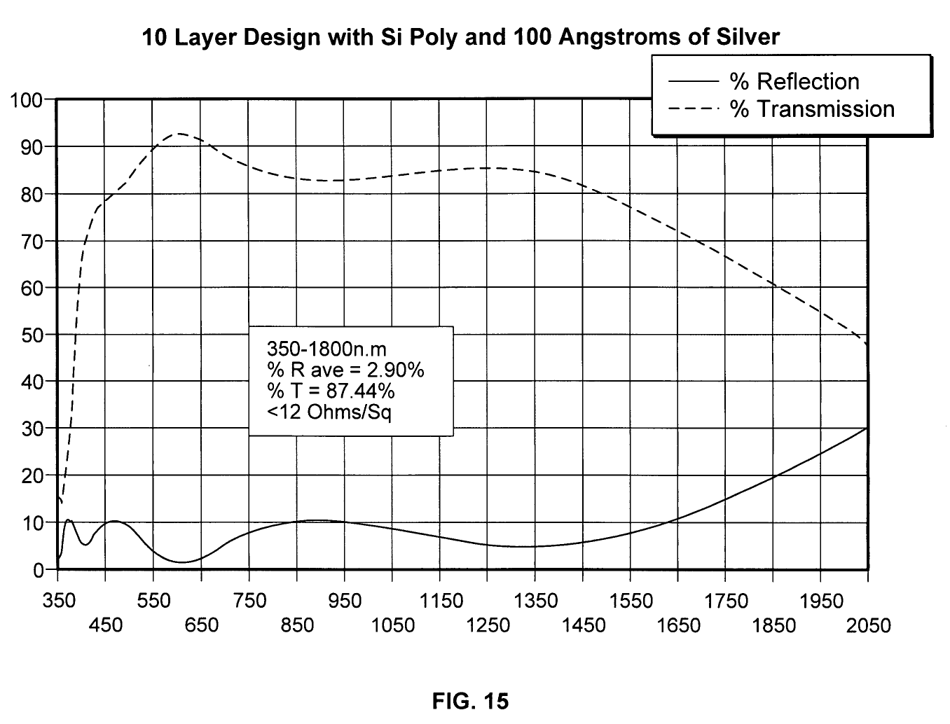

FIG. 15 is a graph of a 10-layer design with an 85 Angstrom thick layer of poly-silicon. This design allows the thickness of the silver layer to be increased to 100 Angstroms. This will give a sheet resistance of about 10 ohms/Sq.

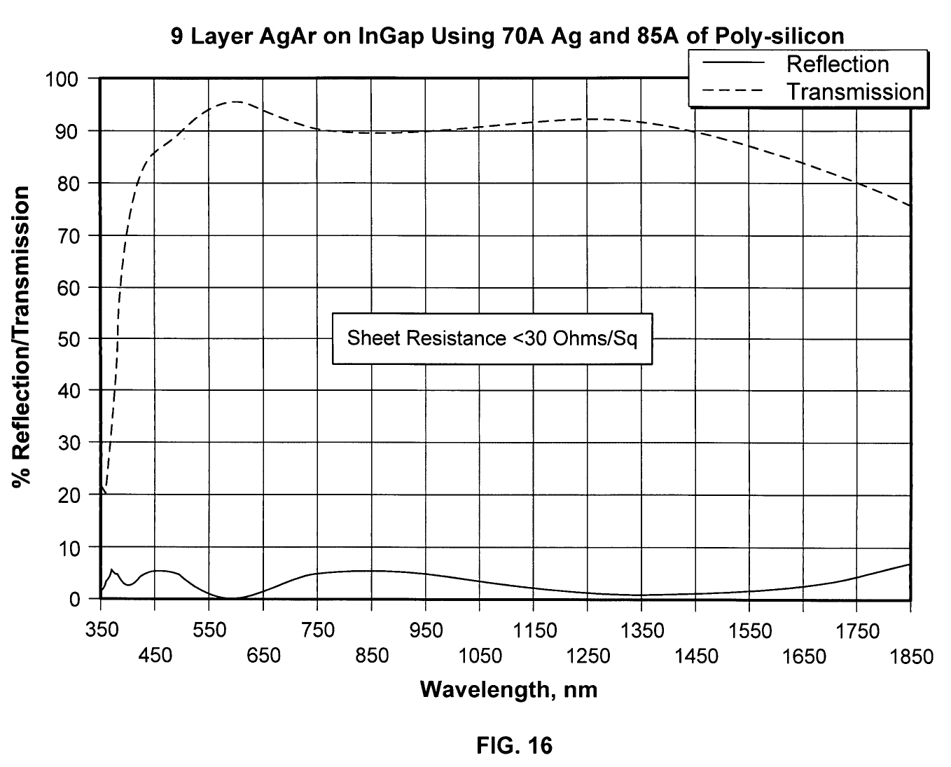

FIG. 16 is a graph of a 9-layer design with an 85 Angstrom thick layer of poly-silicon and 70 Angstroms thick layer of silver. This design gives lower reflection than the design in FIG. 15 and has a sheet resistance of <30 Ohms/Sq, with higher transmission.

Use of multiple silver layers in design. Some of the designs previously shown utilize only one silver layer, which needs to be next to the solar cell surface junction. This limits the silver thickness to about 90-100 Angstroms, due to the optical constants of the silver. When a silver film has a thickness greater than about 100 Angstroms, the reflection at mid infra-red wavelengths, between 900-1000 nm, is approaching very high values and impede the transmission. This limits the electrical conductivity of the single silver layer designs to about 20-30 ohms/sq.

In some embodiments, if a lower sheet resistance than 20-30 ohms/sq is needed, say 10 ohms/sq, two silver layers may be used. These silver layers must be separated by multiple dielectric layers of high and low index, such as in an induced transmission filter used in solar control designs on architectural glass, also known as Double Low-e Designs. (B. V. Landau, “Theory of Induced Transmission in terms of the concept of Equivalent Layers”) J. Pot. Soc. AM. 62, 1258 (1972)

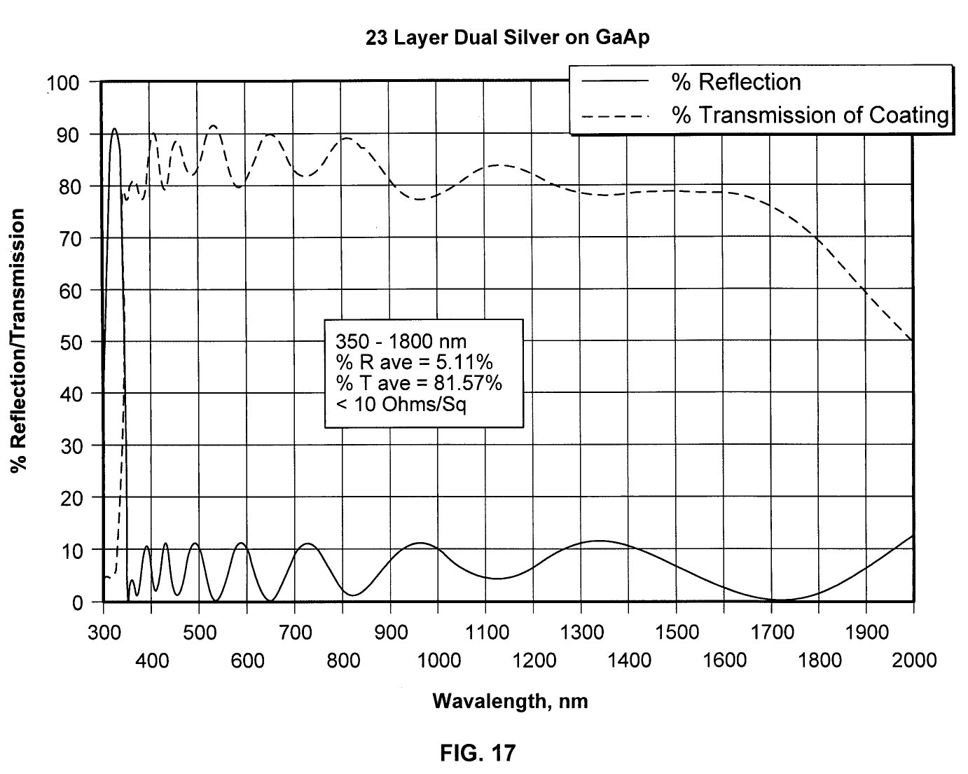

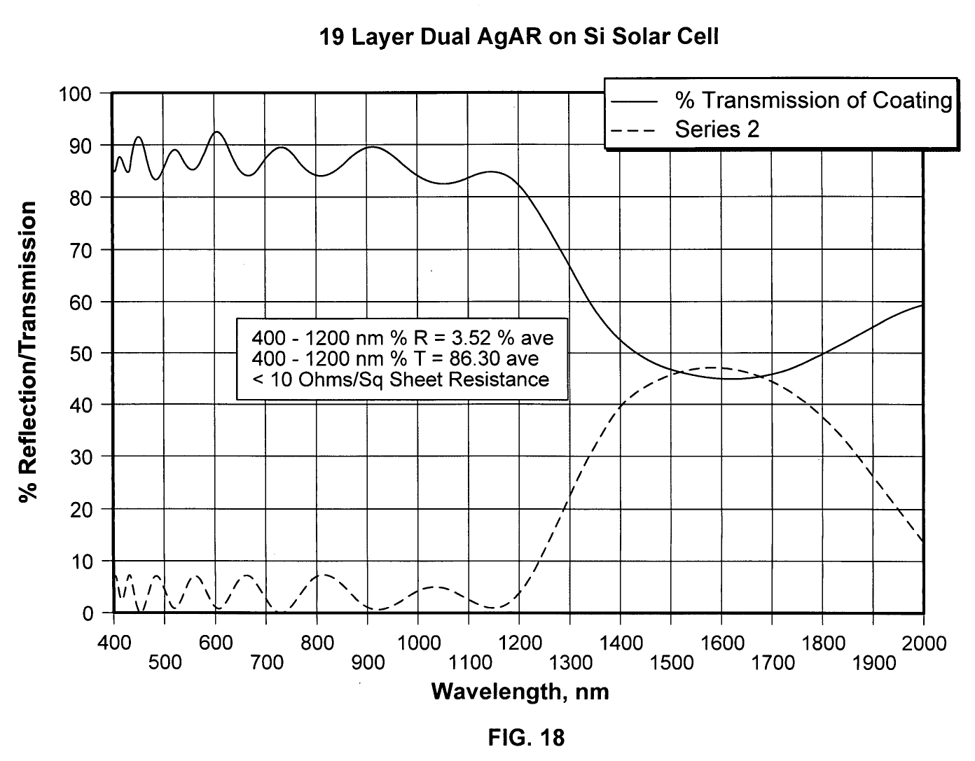

FIG. 17 is a graph of the reflection and transmission of a 23-layer dual silver design. FIG. 18 is a graph of the reflection and transmission of a 19-layer dual silver design for a silicon solar cell. The bandwidth used for the design in FIG. 18 for a silicon solar cell, 400-1100 nm, is much narrower than the design used on multi-junction InGaP cells, 350-1800 nm.

The silver layers must be physically bridged together so they act as a single thick layer, even though multiple dielectric layers separate them. This can be accomplished with an ultrasonic solder gun.

Ultrasonic solder gun. The use of an ultrasonic soldering gun such as that fabricated by SUNBONDER can be used to join the dual silver layers in a design. The gun allows for the fluxless solder of metals, and even exotic materials such as Niobium ceramics, and Glass by the application of heat and ultrasonic energy as delivered via the tip of the ultrasonic iron.

Sonic energy from the tool causes cavitation within the molten solder. The imploding bubbles create shock waves that remove the oxide layers from the parts to be joined. The molten solder then permeates the microscopic pores and cracks in the coatings or substrate and forms an alloy layer on the substrate surfaces, in our case the busbar located on the solar cell surface. The technology can be used to solder a variety of materials, including aluminum, ceramic, copper, gold, silver, tantalum. It can also solder dissimilar materials, such as glass to metal.

Environmental durability. In some embodiments, the silver based coatings are capable of passing the following environmental tests:

### Corrosion Tests:

Salt Fog Test: 72 hours in a 5% (NaCl) Salt Fog at 95-98% relative humidity;

Humidity Test: 96 hours in a humidity cabinet at 60 C;

Boiling Salt Water Test: 1 hour submerged in boiling water with a 5% NaCl solution;

Acid and Base Tests: 5 hours submerged in a 0.1 n Hydrochloric Acid Bath; and
5 hours submerged in a 0.1 n Sodium Hydroxide Bath;

Hydrogen Sulfide Test: The coating will pass 200 hours in a Hydrogen Sulfide Atmosphere as per method 4.2 in ISO 9022-20.

### Mechanical Tests:

Coating Adhesion Test: No evidence of coating removal when 3M-type tape is pressed firmly against the film and removed (snapped) at an 90-degree angle to the coated surface.

Crosshatch Adhesion Test (Plastic substrates only): No evidence of coating removal when a crosshatch pattern is made on the coated surface using a razor blade. 3M-type tape is applied to the pattern and quickly removed at a 90-degree angle to the coated surface.

Alcohol Cheesecloth Test: Mil-spec cheesecloth (#80) is saturated with ethyl alcohol and used with a crock meter. Fifty passes (100 Total) are made across the coated surface with a load of 200 g/cm2.

Rub Eraser Test: The coating is tested by rubbing the coated surface with a standard eraser conforming to Mil-E-12397 mounted in the holding device. A force between 2 and 2/12 ils is applied. All strokes are made on one path for 20 strokes.

These films may also allow one to scratch through the coating with a diamond scribe and pass the Salt-Fog and Humidity tests without any further damage.

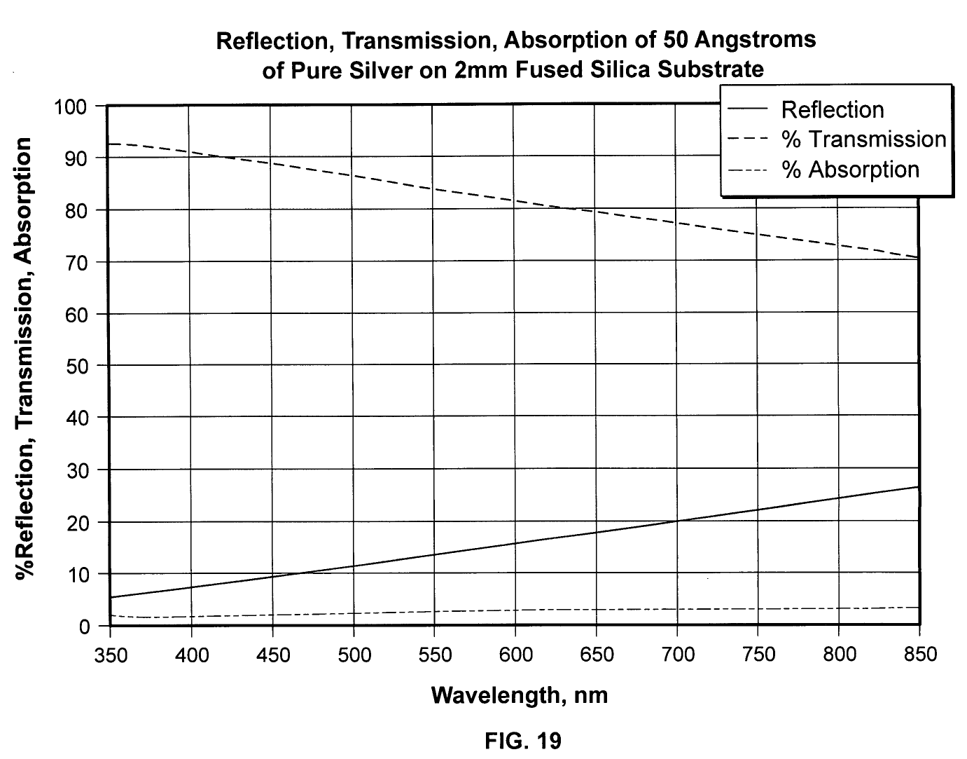

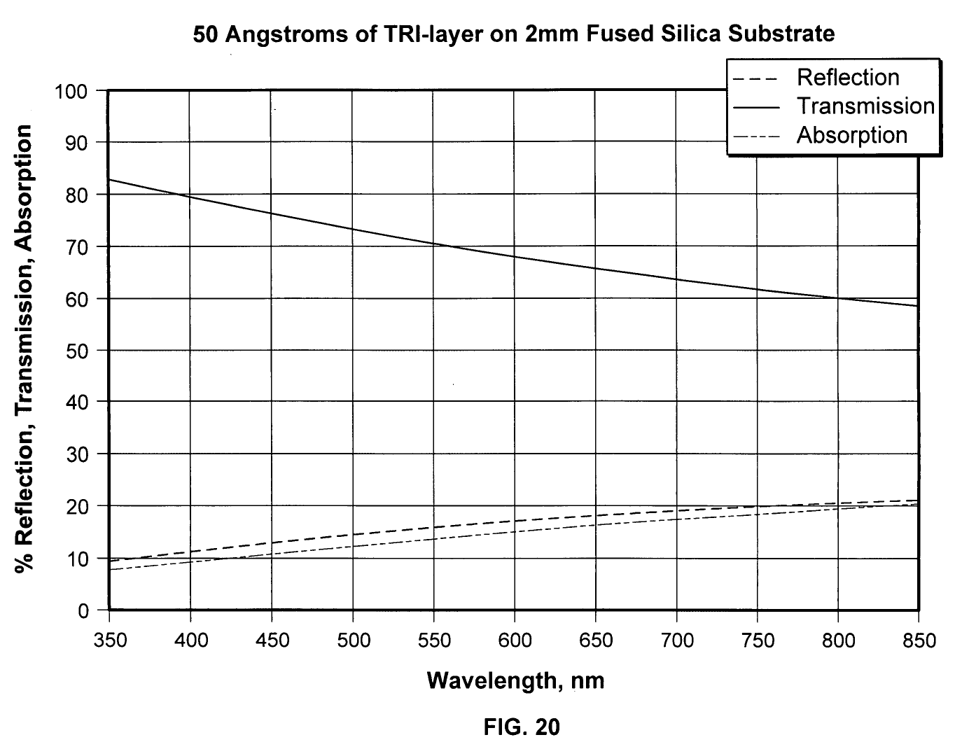

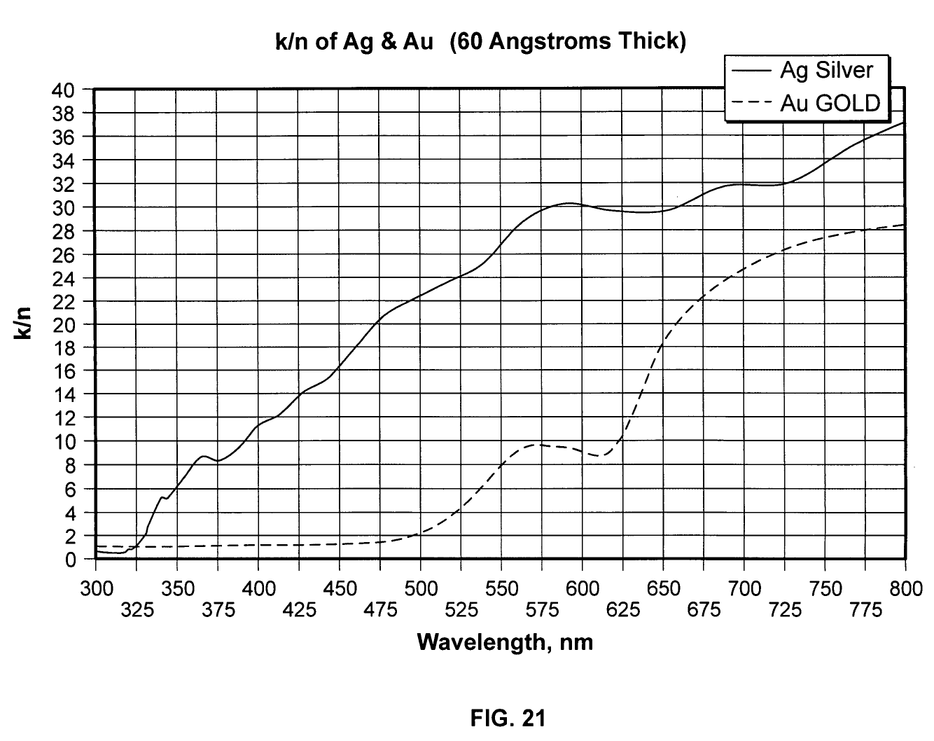

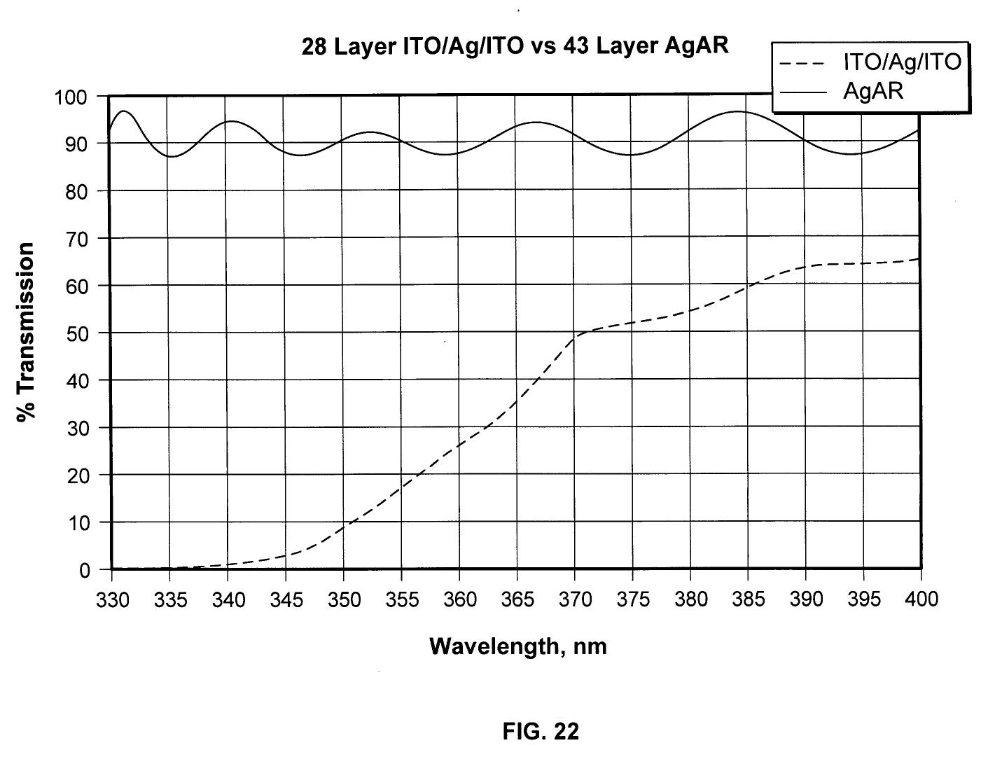

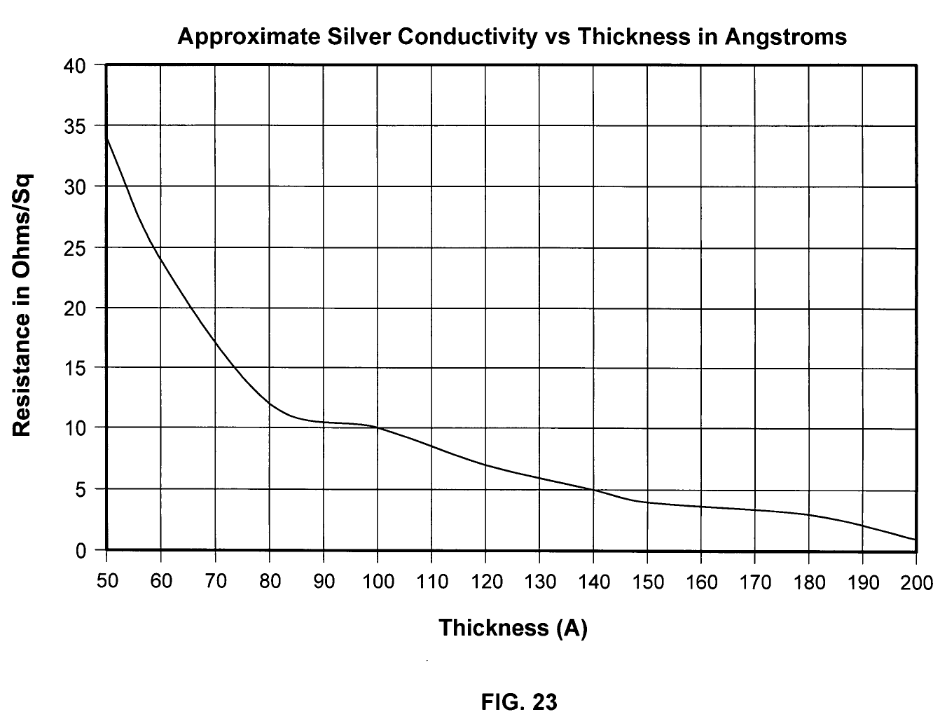

FIG. 19 is a graph of the reflection, transmission, and absorption of 50 Angstroms of pure silver on a 2 mm fused silica substrate. FIG. 20 is a graph of 50 Angstroms of a tri-layer on 2 mm fused substrate. FIG. 21 is a graph of the k/n for gold and silver, both 60 Angstroms thick. FIG. 22 is a graph of the transmission for a 28-layer ITO/Ag/ITO design in comparison to a 43-layer AgAR design. FIG. 23 is a graph of the silver conductivity versus thickness in Angstroms.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A solar cell package, comprising:
a solar cell having an active surface; and
a coating applied to the active surface of the solar cell, wherein the coating comprises a four-layer structure including:
(1) a first Nickel Chromium Nitride layer with a thickness between 5-15 Angstroms inclusive;
(2) a Silver layer, comprising at least 99.999% Silver with a thickness between 40-100 Angstroms inclusive, applied to the first Nickel Chromium Nitride layer;
(3) a second Nickel Chromium Nitride layer with a thickness between 5-15 Angstroms inclusive, applied to the Silver layer; and
(4) a Silicon Nitride layer applied to the second Nickel Chromium Nitride layer.

2. The solar cell package recited in claim 1, wherein the first Nickel Chromium Nitride layer is applied to the active surface.

3. The solar cell package recited in claim 1, wherein the solar cell is a triple junction cell.

4. The solar cell package recited in claim 1, wherein the solar cell is a silicon cell.

5. The solar cell package recited in claim 1, wherein both Nickel Chromium Nitride layers comprise NiCrNₓ.

6. The solar cell package recited in claim 1, wherein both Nickel Chromium Nitride layers comprise Nichrome sputtered in Nitrogen gas.

7. The solar cell package recited in claim 1, wherein both Nickel Chromium Nitride layers comprise Nichrome with an atomic mixture of 80% Nickel 20% Chrome sputtered in 100% Nitrogen gas.

8. The solar cell package recited in claim 1, wherein the Silicon Nitride layer comprises SiₓN_{y}.

9. The solar cell package recited in claim 1, wherein the Silicon Nitride layer comprises Si₃N₄.

10. The solar cell package recited in claim 1, wherein the coating comprises a plurality of the four-layer structures, including a first four-layer structure and a second four-layer structure.

11. The solar cell package recited in claim 10, further comprising at least one via that electrically connects the first and second four-layer structure.

12. The solar cell package recited in claim 10, further comprising at least one via that electrically connects the first and second four-layer structure, wherein the via is below a busbar.

13. The solar cell package recited in claim 10, further comprising an additional Silicon Nitride layer adjacent to the second four layer structure.

14. The solar cell package recited in claim 13, wherein the first Nickel Chromium Nitride layer of the second four layer structure is applied to the additional Silicon Nitride layer.

15. The solar cell package recited in claim 14, wherein the second four layer structure is further from the active surface than the first four layer structure.

16. The solar cell package recited in claim 1, further comprising an additional five-layer structure applied to the four-layer structure, wherein the additional five-layer structure includes:
(1) a first Titanium Dioxide layer, applied to the Silicon Nitride layer;
(2) a Tantalum Oxide layer, applied to the first Titanium Dioxide layer;
(3) a Silicon Dioxide layer, applied to the Tantalum Oxide layer;
(4) a second Titanium Dioxide layer, applied to the Silicon Dioxide layer; and.
5) a Magnesium Fluoride layer, applied to the second Titanium Dioxide layer.

17. The solar cell package recited in claim 1, further comprising an additional sixteen-layer structure applied to the four-layer structure, wherein the additional sixteen-layer structure includes:
(1) a first Titanium Dioxide layer, applied to the Silicon Nitride layer;
(2) a first Magnesium Fluoride layer, applied to the first Titanium Dioxide layer;
(3) a second Titanium Dioxide layer, applied to the first Magnesium Fluoride layer;
(4) a first Silicon Dioxide layer, applied to the second Titanium Dioxide layer;
(5) a first Tantalum Oxide layer, applied to the first Silicon Dioxide layer;
(6) a second Silicon Dioxide layer, applied to the first Tantalum Oxide layer;
(7) a second Tantalum Oxide layer, applied to the second Silicon Dioxide layer;
(8) a third Silicon Dioxide layer, applied to the second Tantalum Oxide layer;
(9) a third Tantalum Oxide layer, applied to the third Silicon Dioxide layer;
(10) a fourth Silicon Dioxide layer, applied to the third Tantalum Oxide layer;
(11) a fourth Tantalum Oxide layer, applied to the fourth Silicon Dioxide layer;
(12) a fifth Silicon Dioxide layer, applied to the fourth Tantalum Oxide layer;
(13) a third Titanium Dioxide layer, applied to the fifth Silicon Dioxide layer;
(14) a sixth Silicon Dioxide layer, applied to the third Titanium Dioxide layer;
(15) a fifth Tantalum Oxide layer, applied to the sixth Silicon Dioxide layer; and
(16) a second Magnesium Fluoride layer, applied to the fifth Tantalum Oxide layer.

18. The solar cell package recited in claim 10, further comprising an additional five-layer structure applied to the four-layer structure, wherein the additional five-layer structure includes:
(1) a first Titanium Dioxide layer, applied to the Silicon Nitride layer;
(2) a Tantalum Oxide layer, applied to the first Titanium Dioxide layer;
(3) a Silicon Dioxide layer, applied to the Tantalum Oxide layer;
(4) a second Titanium Dioxide layer, applied to the Silicon Dioxide layer; and.
5) a Magnesium Fluoride layer, applied to the second Titanium Dioxide layer.

19. The solar cell package recited in claim 10, further comprising an additional sixteen-layer structure applied to the four-layer structure, wherein the additional sixteen-layer structure includes:
(1) a first Titanium Dioxide layer, applied to the Silicon Nitride layer;
(2) a first Magnesium Fluoride layer, applied to the first Titanium Dioxide layer;
(3) a second Titanium Dioxide layer, applied to the first Magnesium Fluoride layer;
(4) a first Silicon Dioxide layer, applied to the second Titanium Dioxide layer;
(5) a first Tantalum Oxide layer, applied to the first Silicon Dioxide layer;
(6) a second Silicon Dioxide layer, applied to the first Tantalum Oxide layer;
(7) a second Tantalum Oxide layer, applied to the second Silicon Dioxide layer;
(8) a third Silicon Dioxide layer, applied to the second Tantalum Oxide layer;
(9) a third Tantalum Oxide layer, applied to the third Silicon Dioxide layer;
(10) a fourth Silicon Dioxide layer, applied to the third Tantalum Oxide layer;
(11) a fourth Tantalum Oxide layer, applied to the fourth Silicon Dioxide layer;
(12) a fifth Silicon Dioxide layer, applied to the fourth Tantalum Oxide layer;
(13) a third Titanium Dioxide layer, applied to the fifth Silicon Dioxide layer;
(14) a sixth Silicon Dioxide layer, applied to the third Titanium Dioxide layer;
(15) a fifth Tantalum Oxide layer, applied to the sixth Silicon Dioxide layer; and
(16) a second Magnesium Fluoride layer, applied to the fifth Tantalum Oxide layer.

20. A method of creating a solar cell package, comprising:
obtaining a solar cell having an active surface;
applying a coating to the active surface of the solar cell, wherein the coating comprises a four-layer structure, including:
(1) applying a first Nickel Chromium Nitride layer with a thickness between 5-15 Angstroms inclusive;
(2) applying a Silver layer, comprising at least 99.999% Silver with a thickness between 40-100 Angstroms inclusive, to the first Nickel Chromium Nitride layer;
(3) applying a second Nickel Chromium Nitride layer with a thickness between 5-15 Angstroms inclusive, to the Silver layer; and
(4) applying a Silicon Nitride layer to the second Nickel Chromium Nitride layer.
